(19) United States
(12) Patent Application Publication
(10) Pub. No.: US 2014/0077816 A1
(43) Pub. Date: Mar. 20, 2014

(54) SENSOR DEVICE AND METHOD FOR PRODUCING A SENSOR DEVICE FOR ACCOMMODATION IN A GALVANIC CELL

(71) Applicants: Mathias BRUENDEL, Stuttgart (DE); Fabian HENRICI, Stuttgart (DE); Daniel PANTEL, Ditzingen (DE)

(72) Inventors: Mathias BRUENDEL, Stuttgart (DE); Fabian HENRICI, Stuttgart (DE); Daniel PANTEL, Ditzingen (DE)

(73) Assignee: ROBERT BOSCH GMBH, Stuttgart (DE)

(21) Appl. No.: 14/028,050

(22) Filed: Sep. 16, 2013

(30) Foreign Application Priority Data
Sep. 17, 2012 (DE) 10 2012 216 563.0

(51) Int. Cl. G01R 31/36

(52) U.S. Cl. CPC G01R 31/3606
USPC 324/426; 29/592.1

(57) ABSTRACT

A sensor device for accommodation in a galvanic cell, having a sensor for detecting a predetermined measured quantity of the galvanic cell. The sensor device includes a sensor housing for receiving the sensor, the sensor being disposed in a recess in the sensor housing, and a measured-quantity transfer medium that covers at least the recess in the sensor housing in fluid-tight fashion and is formed to couple the sensor to an external environment of the sensor device for the transfer of the measured quantity.

### CROSS REFERENCE

The present application claims the benefit under 35 U.S.C. §119 of German Patent Application No. DE 102012216563.0 filed on Sep. 17, 2012, which is hereby expressly incorporated by reference in its entirety.

### FIELD

The present invention relates to a sensor device for accommodation in a galvanic cell and a method for producing a sensor device for accommodation in a galvanic cell.

Monitoring the operating state of the battery cells, e.g., in electric-powered vehicles (lithium-ion batteries) is necessary for the safety of the batteries and for an effective battery-management system. Presently, the operating state of such battery cells is monitored by externally mounted sensors. For example, voltage and temperature of the battery cells are measured.

### SUMMARY

Against this background, the present invention provides an example sensor device for accommodation in a galvanic cell and a method for producing a sensor device for accommodation in a galvanic cell.

A sensor housing that in part has an elastic and/or deformable material and thereby possesses an access for a measured quantity, is suitable for accommodation in a galvanic cell.

According to the approach presented here, an example sensor may be mounted or installed in an open cavity or recess in the sensor housing. By closing the open cavity (especially with the flexible material), the sensor housing enters into no or no significant interactions with an electrolyte of the galvanic cell. To that end, in particular, the recess may be sealed in fluid-tight manner by the measured-quantity transfer medium. In particular, the measured-quantity transfer medium may at least in part have a material that is acid-resistant or solvent-resistant. Because of the flexibility of the elastic material, transfer of a measured quantity, e.g., transfer of a pressure into the sensor housing may be ensured, accompanied at the same time by shielding of the sensor and the electrical contacts from environmental influences. In a further development of the approach proposed here, in order to optimize the measured-quantity transfer and, for example, to increase a pressure dynamic, the cavity enclosed by a housing and foil may be filled by a fluid. A type of construction and dimensions of such a battery-suitable sensor packing does not have to be changed substantially compared to a standard sensor packing.

With the example embodiments presented here, a possibility is provided or improved to dispose sensors for monitoring the operating state of an electrochemical storage within the individual battery cells. Advantageously, measured quantities such as voltage, temperature or pressure may thereby be measured more precisely, which is becoming increasingly important within the framework of today's developments.

Therefore, the problem of the environmental conditions prevailing within the battery cell, which are not suitable for classic packing materials such as mold compound, PCB, adhesive agents, gels, etc., since they may be affected by chemical reactions with the electrolyte and decompose, is able to be solved. Using the approach described here, endangerment both of the sensors and of the cell stability by a possible introduction of foreign materials into the electrolyte may be avoided effectively. It is therefore possible to dispense with concepts which lead to markedly larger sizes of the sensors, such as completely enveloping the sensors with a battery-suitable foil.

A sensor device for accommodation in a galvanic cell is described, having a sensor for detecting a predetermined measured quantity of the galvanic cell, the sensor device having the following features:

a sensor housing for receiving the sensor, the sensor being disposed in a recess in the sensor housing; and

a measured-quantity transfer medium that covers at least the recess in the sensor housing in fluid-tight fashion, and is formed to couple the sensor to an external environment of the sensor device for the transfer of the measured quantity.

For example, the galvanic cell may be an accumulator or part of an accumulator for powering an electric-powered vehicle or hybrid vehicle. The sensor device may be used, for instance, to monitor the operating state of the galvanic cell. In this context, the sensor device may be disposed within an enclosure of the galvanic cell and may be in contact with an electrolyte of the galvanic cell. The measured quantity of the galvanic cell to be sensed by the sensor may be a voltage, a temperature or a pressure prevailing in the galvanic cell. For example, the sensor housing may be made of metal or plastic. In particular, the sensor housing may have the characteristic that is does not react with the galvanic-cell electrolyte surrounding the sensor device. The recess may be formed in such a way that walls of the sensor housing forming the recess project above the sensor when it is within the recess. For example, the recess may have the shape of a rectangle. The sensor may be disposed in the recess so as to be set apart from the walls of the sensor housing. The sensor housing may have at least one lead-through for the electrical contacting of the sensor to a voltage supply located outside of the sensor device. The measured-quantity transfer medium may be disposed on the sensor housing in such a way that it touches the sensor, or alternatively, in such a way that it is set apart from the sensor. The measured-quantity transfer medium may be formed to permit or to make it easier for the sensor to detect the measured quantity. In particular, the measured-quantity transfer medium may be implemented to ensure a transfer of pressure between the external environment of the sensor device and the sensor. Moreover, the measured-quantity transfer medium may be implemented to prevent interactions between cell elements, e.g., the electrolyte of the galvanic cell, and the sensor, and to protect both the galvanic cell and the sensor from adverse mechanical or chemical influence.

According to one specific embodiment, the measured-quantity transfer medium may have an elastic foil. Thus, the transfer of the measured quantity and particularly the pressure transfer may be ensured particularly efficiently. Moreover, weight and size of the sensor device may be reduced advantageously by the use of a foil.

Furthermore, the measured-quantity transfer medium may be joined in fluid-tight fashion to an edge area of the sensor housing surrounding the recess, and/or the measured-quantity transfer medium at least in part has a material that is resistant to acid and/or resistant to solvent. For example, parts of the electrolyte may thus advantageously be prevented from penetrating into the recess and impairing the sensor, e.g., damaging it by decomposition. Moreover, the fluid-tight joint is able to ensure that a fluid possibly located in the recess cannot be pressed out of it.

In particular, the measured-quantity transfer medium may include a metal and/or a plastic material. For instance, the measured-quantity transfer medium may be implemented as a plastic-coated metal foil or alternatively as a metal-coated plastic film. Consequently, the advantages of both materials, thus here, especially robustness, acid resistance and flexibility, may be given to the measured-quantity transfer medium.

According to a further specific embodiment, the recess in the sensor housing may additionally be filled with a fluid that at least partially surrounds the sensor and is coupled to the external environment of the sensor device with the aid of the measured-quantity transfer medium for the transfer of the measured quantity. The fluid may be a gel or an oil. For example, the sensor may be immersed completely in the fluid. Advantageously, the transfer of pressure from the galvanic cell to the sensor may thus be made even more dynamic and the measured quantity may be acquired more quickly and accurately accordingly.

In particular, the measured-quantity transfer medium may be implemented to transfer a pressure to the sensor. Thus, for example, it is possible to detect an expansion of the galvanic cell which allows conclusions, important for the functioning of the galvanic cell, about a state of charge or a state of health of the galvanic cell.

For instance, the sensor housing may have a rigid form. A rigid form may be understood to be a non-deformable construction of the sensor housing, for example. Thus, the sensor housing may be implemented as a premold housing or mold-premold housing, for instance. This specific embodiment has the advantages that the sensor is able to be protected optimally from mechanical damage, and at the same time, the measured quantity is able to be transferred via the measured-quantity transfer medium at a suitable location to the sensor.

Furthermore, the sensor housing may have an electronic circuit which may be connected to the sensor by an electric line. The electronic circuit may be designed to process sensor signals and to output control signals and/or data signals as a function thereof. For example, the electronic circuit may be in the form of an application-specific integrated circuit (ASIC) and may be connected via interfaces, for instance, to a battery-management system of a vehicle. For example, the electronic circuit may be embedded in the housing. Advantageously, the electronic circuit is thus protected particularly well and in addition, may be disposed close to the sensor, so that a measured value acquired by the sensor may be passed on especially quickly to the electronic circuit for evaluation.

Furthermore, an example method is described for producing a sensor device for accommodation in a galvanic cell, the method includes the following:

Providing a sensor housing with a recess for receiving a sensor;

Placing within the recess, a sensor for detecting a predetermined measured quantity of the galvanic cell; and

Covering at least the recess in fluid-tight fashion with a measured-quantity transfer medium which is formed to couple the sensor to an external environment of the sensor device.

The example method may be carried into effect by suitable equipment, in doing which, the steps of providing, placing and covering may be executed in suitable devices of the equipment.

According to one specific embodiment, the method may further have a step of joining the measured-quantity transfer medium in fluid-tight fashion to an edge area of the sensor housing surrounding the recess. The fluid-tight joint may be produced by adhesive bonding or thermal joining, for example, and has the advantage that components of the galvanic cell surrounding the sensor device are not able to penetrate into the recess in the sensor housing, nor is a fluid possibly present in the recess able to seep into the galvanic cell. Thus, decomposition processes are able to be avoided effectively, both in the galvanic cell and in the sensor.

In the following, the present invention is explained in detail by way of example, with reference to the figures.

### BRIEF DESCRIPTION OF THE DRAWINGS

FIG. 1 shows a cross-section through a sensor device for accommodation in a galvanic cell, according to one exemplary embodiment of the present invention.

FIG. 2 shows the sensor device from FIG. 1 in a further cross-sectional representation, filled with a fluid, according to a further exemplary embodiment of the present invention.

FIG. 3 shows a cross-section through a sensor device having an ASIC integrated in the sensor housing, according to one exemplary embodiment of the present invention.

FIG. 4 shows a flow chart of a method for producing a sensor device for accommodation in a galvanic cell, according to one exemplary embodiment of the present invention.

### DETAILED DESCRIPTION OF EXAMPLE EMBODIMENTS

In the following description of preferred exemplary embodiments of the present invention, the same or similar reference numerals are used for the similarly functioning elements shown in the various figures, a repeated description of these elements being omitted.

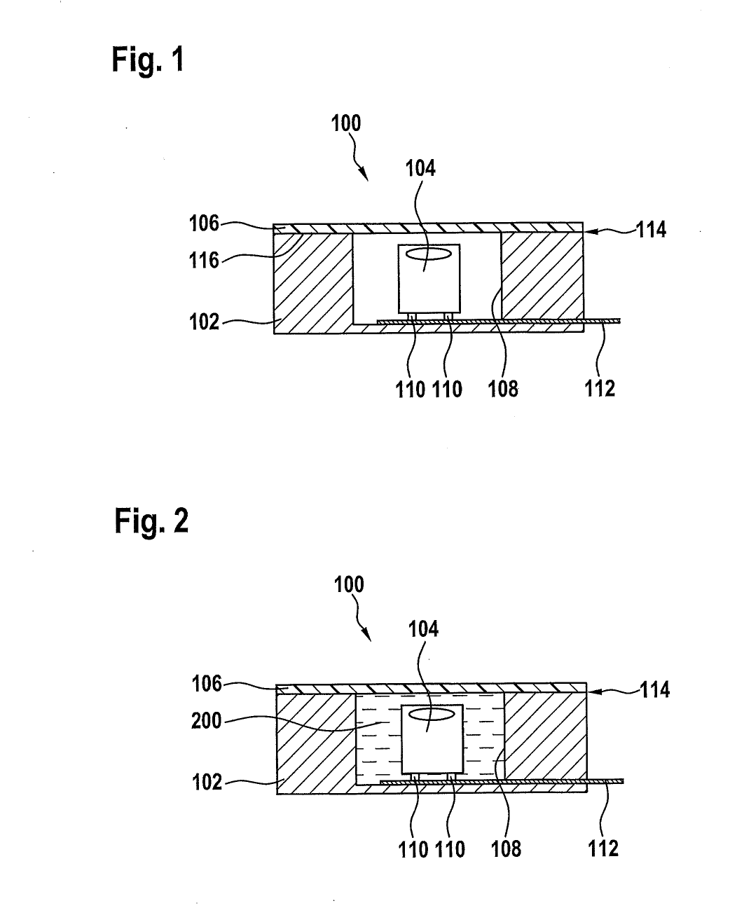

FIG. 1, with the aid of a cross-section through an exemplary embodiment of a sensor device 100, shows the principle presented here for a media-resistant sensor housing for battery cells. Sensor device 100 is designed to be disposed in the interior of a galvanic cell (not shown) and to detect one or more measured quantities of the galvanic cell such as pressure or temperature and, for example, to pass them on to a battery-management system of a vehicle. Sensor device 100 includes a sensor housing 102, a sensor 104 and a measured-quantity transfer medium 106. Sensor housing 102 has a recess or cavity 108 in which sensor 104 is placed. Sensor 104 is realized here as a pressure sensor. Alternatively, however, sensor 104 may also be a temperature sensor or voltmeter, for instance.

As the illustration in FIG. 1 shows, sensor 104 is dimensioned and placed in recess 108 in such a way that laterally, it is set apart from the walls of sensor housing 102, and upward with its detecting side, it is set apart from measured-quantity transfer medium 106. The sensor is coupled via each electrical contact 110 to an electric line 112 which runs in a feed-through opening through sensor housing 102 and is implemented to supply sensor 104 with voltage. Measured-quantity transfer medium 106 is realized here as an elastic foil whose flexible material allows pressure to be transferred from an external environment of sensor device 100 to sensor 104. For instance, flexible foil 106 may be a plastic-coated metal foil or a metal-coated plastic film as is used to produce “pouch cells”, for example, and which in general is regarded as battery-suitable. Sensor housing 102 is made of a material that enters into no significant interactions with the electrolyte, or is protected by a protective layer from a reaction with the electrolyte. In view of the use determined for sensor device 100 presented here, the external environment may be equated with an interior of a galvanic cell in which sensor device 100 is located. A fluid-tight joint 114 between an edge area 116 of sensor housing 102 surrounding recess 108 and measured-quantity transfer medium 106 ensures that no components of the galvanic cell in which sensor device 100 is situated, e.g., parts of the electrolyte, are able to penetrate into recess 108. Fluid-tight joint 114 may be produced, e.g., by laser welding, sealing or thermal joining or adhesive bonding.

From the representation in FIG. 1, it is apparent that sensor 104 is mounted in cavity 108 of sensor housing 102. Housing 102 enters into no significant interactions with the electrolyte of the surrounding galvanic cell. Electrical contacts 110 of sensor 104 are led to the outside through one or more fluid-tight electrical lead-throughs in housing 102. Flexible foil 106 which, like sensor housing 102, enters into no significant interactions with the electrolyte, is secured in fluid-tight fashion to housing 102 in such a way during the manufacturing process of sensor device 100 that previously open cavity 108 is sealed by the material, e.g., by adhesive bonding or thermal joining. Because of the flexibility of the material of measured-quantity transfer medium 106, the transfer of pressure into sensor housing 102 is ensured, accompanied at the same time by shielding of sensor 104 and electrical contacts 110 from environmental influences. To optimize the pressure transfer and to increase the dynamics, cavity 108 enclosed by housing 102 and foil 106 may be filled by a fluid, as shown in the following FIG. 2. The type of construction and dimensions of battery-suitable sensor packing 102 are not changed substantially compared to a standard sensor packing.

FIG. 2, again in a cross-sectional representation, shows sensor device 100 from FIG. 1 in a further exemplary realization. For better transfer of pressure to sensor 104, cavity 108 sealed by flexible foil 106 is filled here with a fluid 200. Fluid 200 here is in the form of a gel. Alternatively, an oil may also be used, for example. Fluid-tight joint 114 ensures that electrolyte from the galvanic cell is not able to penetrate into the recess, nor is fluid 200 from recess 108 able to penetrate into the galvanic cell surrounding sensor device 100.

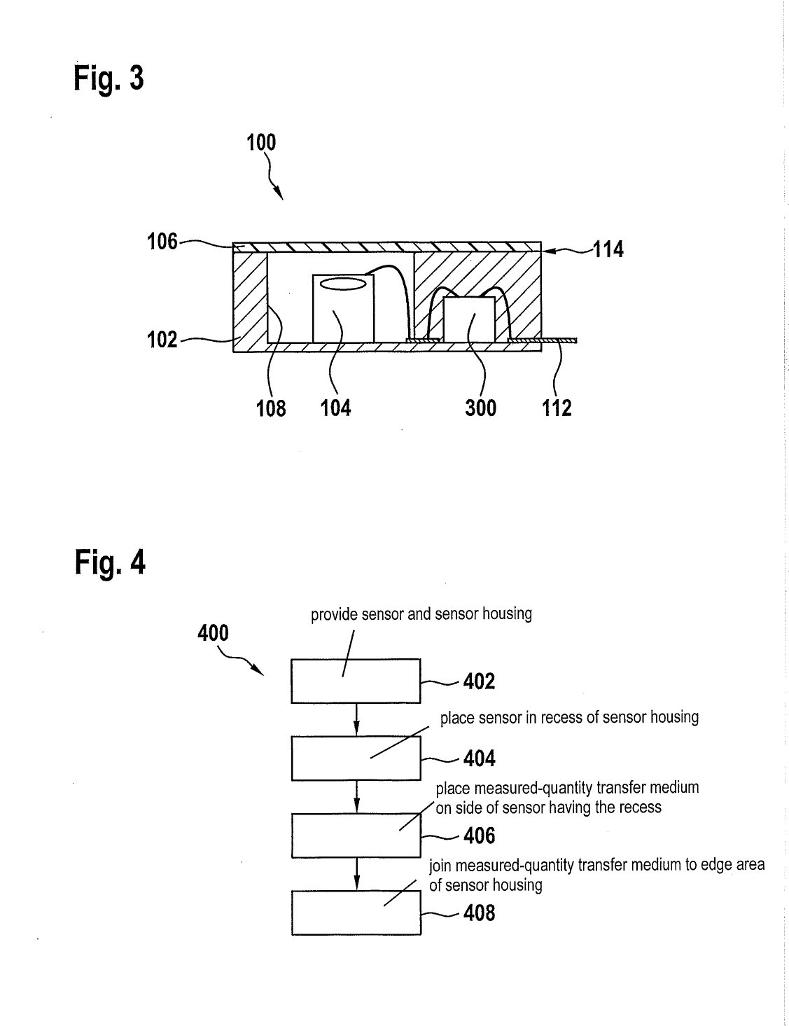

FIG. 3 shows an alternative exemplary embodiment of sensor device 100 with the aid of a further cross-sectional representation. Here, sensor device 100 is additionally equipped with an application-specific integrated circuit (ASIC) 300. As the representation in FIG. 3 shows, sensor housing 102 is implemented here as a mold-premold, and ASIC 300 is permanently embedded in a wall of sensor housing 102. ASIC 300 is coupled via electric line 112 and additional lines to sensor 104 and is able to retrieve the measurement data from sensor 104 by a short path, evaluate it and pass on the results via line 112 to the battery-management system (not shown) of the vehicle, for example.

In particular, FIGS. 1 through 3 describe exemplary sensor housing 102, which is suitable for introduction into a battery cell and which has a pressure access via elastic closure 106 of recess 108. A standard sensor packing, e.g., a mold-premold housing, a premold housing or a metal housing, forms the skeletal framework of this sensor housing 102. Sensor 104 lies in cavity 108 of the standard packing having at least one opening to the outside. This opening is closed in fluid-tight manner by additional battery-suitable flexible foil 106 which ensures the transfer of pressure into cavity 108 or to sensor 104 and therefore protects sensor 104 from harsh environmental conditions.

FIG. 4 shows a flow chart of an exemplary embodiment of a method 400 for producing a sensor device for accommodation in a galvanic cell. In a step 402, a sensor housing and a sensor are provided, the sensor housing in particular having a recess or cavity for receiving the sensor. The sensor is designed to detect a predetermined measured quantity of the galvanic cell, and in a step 404, is placed in the recess in the sensor housing. In a step 406, a measured-quantity transfer medium, e.g., an elastic and battery-suitable foil, is placed on a side of the sensor housing having the recess, and in a step 408, is joined in fluid-tight fashion to an edge area of the sensor housing surrounding the recess by adhesive bonding or thermal joining.

In summary, the present invention presented here relates to sealing of a cavity of a sensor housing by a flexible foil to protect the sensor and contactings, the flexible foil allowing a transfer of a pressure. Continuing, by filling the cavity with a fluid, the pressure transfer is optimized and the dynamics are increased by reducing the compressibility.

The exemplary embodiments described and illustrated in the figures are selected only by way of example. Different exemplary embodiments may be combined with each other completely or in terms of individual features. One exemplary embodiment may also be supplemented by features from another exemplary embodiment.

Moreover, method steps according to the present invention may be repeated and executed in a sequence other than that described.

If an exemplary embodiment includes an “and/or” link between a first feature and a second feature, this is to be read that the exemplary embodiment according to one embodiment has both the first feature and the second feature, and according to a further embodiment, has either only the first feature or only the second feature.

What is claimed is:

1. A sensor device for accommodation in a galvanic cell, comprising:
a sensor to detect a predetermined measured quantity of the galvanic cell;
a sensor housing to receive the sensor, the sensor being disposed in a recess in the sensor housing; and
a measured-quantity transfer medium that covers at least the recess of the sensor housing in fluid-tight fashion, and is formed to couple the sensor to an external environment of the sensor device for transfer of the measured quantity.

2. The sensor device as recited in claim 1, wherein the measured-quantity transfer medium includes an elastic foil.

3. The sensor device as recited in claim 1, wherein at least one of: i) the measured-quantity transfer medium is joined in fluid-tight fashion to an edge area of the sensor housing surrounding the recess, ii) the measured-quantity transfer medium at least in part has a material which is acid-resistant, and iii) the measured-quantity transfer medium is at least in part solvent-resistant.

4. The sensor device as recited in claim 1, wherein the measured-quantity transfer medium includes at least one of a metal material and a plastic material.

5. The sensor device as recited in claim 1, wherein the recess in the sensor housing is additionally filled with a fluid which at least partially surrounds the sensor and is coupled to the external environment of the sensor device by the measured-quantity transfer medium for the transfer of the measured quantity.

6. The sensor device as recited in claim 1, wherein the measured-quantity transfer medium is formed to transfer a pressure to the sensor.

7. The sensor device as recited in claim 1, wherein the sensor housing has a rigid form.

8. The sensor device as recited in claim 1, wherein an electronic circuit is embedded in the sensor housing and is connected to the sensor by an electric line.

9. A method for producing a sensor device for accommodation in a galvanic cell, the method comprising:
providing a sensor housing with a recess for receiving a sensor;
placing within the recess, a sensor for detecting a predetermined measured quantity of the galvanic cell; and
covering at least the recess in fluid-tight fashion with a measured-quantity transfer medium which is formed to couple the sensor to an external environment of the sensor device for transfer of the measured quantity.

10. The method as recited in claim 9, further comprising:
joining the measured-quantity transfer medium in fluid-tight fashion to an edge area of the sensor housing surrounding the recess.
